(19) United States
(12) Patent Application Publication
(10) Pub. No.: US 2014/0002805 A1
(43) Pub. Date: Jan. 2, 2014

(54) Electrostatic Clamp Apparatus And Lithographic Apparatus

(71) Applicants: Vadim Yevgenyevich Banine, Deurne (NL); Erik Roelof Loopstra, Eindhoven (NL); Theodorus Petrus Maria Cadee, Asten (NL); Johannes Antonius Gerardus Akkermans, Eindhoven (NL); Luigi Scaccabarozzi, Valkenswaard (NL); Christiaan Louis Valentin, Eindhoven (NL)

(72) Inventors: Vadim Yevgenyevich Banine, Deurne (NL); Erik Roelof Loopstra, Eindhoven (NL); Theodorus Petrus Maria Cadee, Asten (NL); Johannes Antonius Gerardus Akkermans, Eindhoven (NL); Luigi Scaccabarozzi, Valkenswaard (NL); Christiaan Louis Valentin, Eindhoven (NL)

(73) Assignee: ASML Netherelands B.V., Veldhoven (NL)

(21) Appl. No.: 14/004,199

(22) PCT Filed: Jan. 18, 2012
(86) PCT No.: PCT/EP2012/050727

§ 371 Date: Sep. 10, 2013

Related U.S. Application Data
(60) Provisional application No. 61/451,803, filed on Mar. 11, 2011.

(51) Int. Cl. H01L 21/683

(52) U.S. Cl. CPC H01L 21/6833
USPC 355/72; 361/234

(57) ABSTRACT

Disclosed is an electrostatic clamp apparatus (500) constructed to support a patterning device (505) of a lithographic apparatus, comprising a support structure against which said patterning device is supported, clamping electrodes (525) for providing a clamping force between the support structure and patterning device, and an array of capacitive sensors (660) operable to measure the shape of said patterning device.

### CROSS-REFERENCE TO RELATED APPLICATIONS

This application claims the benefit of U.S. provisional application 61/451,803, which was filed on 11 Mar. 2011, and which is incorporated herein in its entirety by reference.

### FIELD

The present invention relates to a lithographic apparatus and a specifically to electrostatic clamp apparatus for use on lithographic apparatus.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned.

Lithography is widely recognized as one of the key steps in the manufacture of ICs and other devices and/or structures. However, as the dimensions of features made using lithography become smaller, lithography is becoming a more critical factor for enabling miniature IC or other devices and/or structures to be manufactured.

A theoretical estimate of the limits of pattern printing can be given by the Rayleigh criterion for resolution as shown in equation (1):

$$CD = {k}_{1} * \frac{λ}{NA} \qquad ( 1 )$$

where λ is the wavelength of the radiation used, NA is the numerical aperture of the projection system used to print the pattern, k1 is a process dependent adjustment factor, also called the Rayleigh constant, and CD is the feature size (or critical dimension) of the printed feature. It follows from equation (1) that reduction of the minimum printable size of features can be obtained in three ways: by shortening the exposure wavelength λ, by increasing the numerical aperture NA or by decreasing the value of k1.

In order to shorten the exposure wavelength and, thus, reduce the minimum printable size, it has been proposed to use an extreme ultraviolet (EUV) radiation source. EUV radiation is electromagnetic radiation having a wavelength within the range of 5-20 nm, for example within the range of 13-14 nm. It has further been proposed that EUV radiation with a wavelength of less than 10 nm could be used, for example within the range of 5-10 nm such as 6.7 nm or 6.8 nm. Such radiation is termed extreme ultraviolet radiation or soft x-ray radiation. Possible sources include, for example, laser-produced plasma sources, discharge plasma sources, or sources based on synchrotron radiation provided by an electron storage ring.

EUV radiation may be produced using a plasma. A radiation system for producing EUV radiation may include a laser for exciting a fuel to provide the plasma, and a source collector module for containing the plasma. The plasma may be created, for example, by directing a laser beam at a fuel, such as particles of a suitable material (e.g. tin), or a stream of a suitable gas or vapor, such as Xe gas or Li vapor. The resulting plasma emits output radiation, e.g., EUV radiation, which is collected using a radiation collector. The radiation collector may be a mirrored normal incidence radiation collector, which receives the radiation and focuses the radiation into a beam. The source collector module may include an enclosing structure or chamber arranged to provide a vacuum environment to support the plasma. Such a radiation system is typically termed a laser produced plasma (LPP) source.

EUV masks or reticles have to be chucked on an electrostatic chuck. The presence of particles in the order of μm size trapped between burls and the reticle backside can produce (in-plane and out-of-plane) deformation of the reticle which can compromise overlay. Calculations show that μm size particles on the backside may lead to a deformity on the frontside with height in the order of nm, which in turn leads to overlay errors sufficient to put the tool out of specification.

In fact, on the backside there could be many particles, but only a few of them (or none) may necessarily lead to deformities large enough on the frontside to be problematic (in fact, particles may be squashed or crushed instead of producing a deformation). Furthermore it would be beneficial to be able to measure frontside deformations (non-flatness) due to other sources; for example, temperature.

Up to now, no suitable solution for these issues has been devised, largely due to the fact that the frontside reticle surface is patterned with an arbitrary pattern, while conventional level sensors work on flat surfaces.

It is desirable to provide an apparatus which can be used to identify and/or measure such deformities in a reticle or mask.

According to an aspect of the invention, there is provided an electrostatic clamp apparatus constructed to support a patterning device of a lithographic apparatus, comprising a support structure against which said patterning device is supported, clamping electrodes for providing a clamping force between the support structure and patterning device, and an array of capacitive sensors operable to measure the shape of said patterning device.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIG. 2 is a more detailed view of the apparatus 100:

FIG. 3 is a more detailed view of the source collector module SO of the apparatus of FIGS. 1 and 2;

FIG. 4 shows a lithographic apparatus according to an alternative embodiment of the invention;

FIG. 5 is a cut away side view of an electrostatic clamp arrangement according to an embodiment of the invention;

FIG. 6 is a top view of the capacitive sensor array of the arrangement of FIG. 5;

FIG. 7 is a cut away side view of an electrostatic clamp arrangement according to a further embodiment of the invention;

FIG. 8 is a top view of the capacitive sensor array of the arrangement of FIG. 7;

FIG. 9 is a cut away side view of a electrostatic clamp arrangement according to a further embodiment of the invention;

FIGS. 10a and 10b show the arrangement of FIG. 9 with the clamp inactive and active respectively;

FIGS. 11a and 11b show a top view and side view respectively of a third main embodiment of the invention;

FIG. 12 shows the embodiment of FIGS. 11a and 11b measuring a reticle profile between yₙ₀ and yₙ₁;

FIG. 13 illustrates a first simplified measurement scenario using the embodiment of FIGS. 11a and 11b;

### DETAILED DESCRIPTION

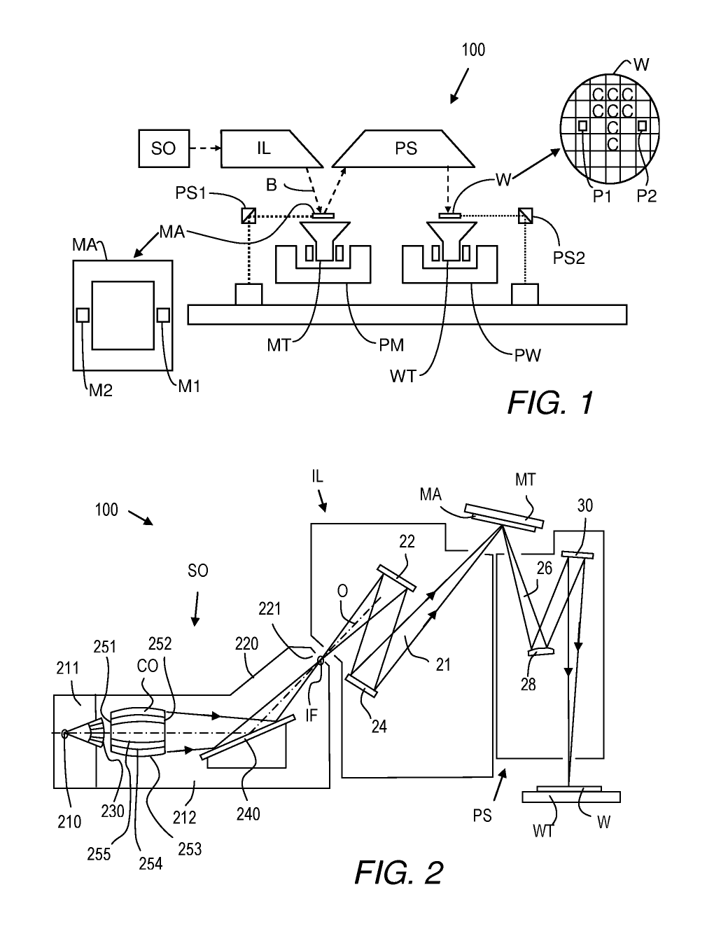

FIG. 1 schematically depicts a lithographic apparatus 100 including a source collector module SO according to one embodiment of the invention. The apparatus comprises:
an illumination system (illuminator) IL configured to condition a radiation beam B (e.g. EUV radiation).
a support structure (e.g. a mask table) MT constructed to support a patterning device (e.g. a mask or a reticle) MA and connected to a first positioner PM configured to accurately position the patterning device;
a substrate table (e.g. a wafer table) WT constructed to hold a substrate (e.g. a resist-coated wafer) W and connected to a second positioner PW configured to accurately position the substrate; and
a projection system (e.g. a reflective projection system) PS configured to project a pattern imparted to the radiation beam B by patterning device MA onto a target portion C (e.g. comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure MT holds the patterning device MA in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system.

The term “patterning device” should be broadly interpreted as referring to any device that can be used to impart a radiation beam with a pattern in its cross-section such as to create a pattern in a target portion of the substrate. The pattern imparted to the radiation beam may correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The projection system, like the illumination system, may include various types of optical components, such as refractive, reflective, magnetic, electromagnetic, electrostatic or other types of optical components, or any combination thereof, as appropriate for the exposure radiation being used, or for other factors such as the use of a vacuum. It may be desired to use a vacuum for EUV radiation since other gases may absorb too much radiation. A vacuum environment may therefore be provided to the whole beam path with the aid of a vacuum wall and vacuum pumps.

As here depicted, the apparatus is of a reflective type (e.g. employing a reflective mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

Referring to FIG. 1, the illuminator IL receives an extreme ultra violet radiation beam from the source collector module SO. Methods to produce EUV light include, but are not necessarily limited to, converting a material into a plasma state that has at least one element, e.g., xenon, lithium or tin, with one or more emission lines in the EUV range. In one such method, often termed laser produced plasma (“LPP”) the required plasma can be produced by irradiating a fuel, such as a droplet, stream or cluster of material having the required line-emitting element, with a laser beam. The source collector module SO may be part of an EUV radiation system including a laser, not shown in FIG. 1, for providing the laser beam exciting the fuel. The resulting plasma emits output radiation, e.g., EUV radiation, which is collected using a radiation collector, disposed in the source collector module. The laser and the source collector module may be separate entities, for example when a CO₂ laser is used to provide the laser beam for fuel excitation.

In such cases, the laser is not considered to form part of the lithographic apparatus and the radiation beam is passed from the laser to the source collector module with the aid of a beam delivery system comprising, for example, suitable directing mirrors and/or a beam expander. In other cases the source may be an integral part of the source collector module, for example when the source is a discharge produced plasma EUV generator, often termed as a DPP source.

The illuminator IL may comprise an adjuster for adjusting the angular intensity distribution of the radiation beam. Generally, at least the outer and/or inner radial extent (commonly referred to as a-outer and a-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross-section.

The radiation beam B is incident on the patterning device (e.g., mask) MA, which is held on the support structure (e.g., mask table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of the radiation beam B. Similarly, the first positioner PM and another position sensor PS1 can be used to accurately position the patterning device (e.g. mask) MA with respect to the path of the radiation beam B. Patterning device (e.g. mask) MA and substrate W may be aligned using mask alignment marks M1, M2 and substrate alignment marks P1, P2.

The depicted apparatus could be used in at least one of the following modes:
1. In step mode, the support structure (e.g. mask table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.
2. In scan mode, the support structure (e.g. mask table) MT and the substrate table WT are scanned synchronously while a pattern imparted to the radiation beam is projected onto a target portion C (i.e. a single dynamic exposure). The velocity and direction of the substrate table WT relative to the support structure (e.g. mask table) MT may be determined by the (de-)magnification and image reversal characteristics of the projection system PS.
3. In another mode, the support structure (e.g. mask table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

FIG. 2 shows the apparatus 100 in more detail, including the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing an at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure, as known in the art.

The collector chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the wafer stage or substrate table WT.

More elements than shown may generally be present in illumination optics unit IL and projection system PS. The grating spectral filter 240 may optionally be present, depending upon the type of lithographic apparatus. Further, there may be more mirrors present than those shown in the Figures, for example there may be 1-6 additional reflective elements present in the projection system PS than shown in FIG. 2.

Collector optic CO, as illustrated in FIG. 2, is depicted as a nested collector with grazing incidence reflectors 253, 254 and 255, just as an example of a collector (or collector mirror). The grazing incidence reflectors 253, 254 and 255 are disposed axially symmetric around an optical axis O and a collector optic CO of this type is preferably used in combination with a discharge produced plasma source, often called a DPP source.

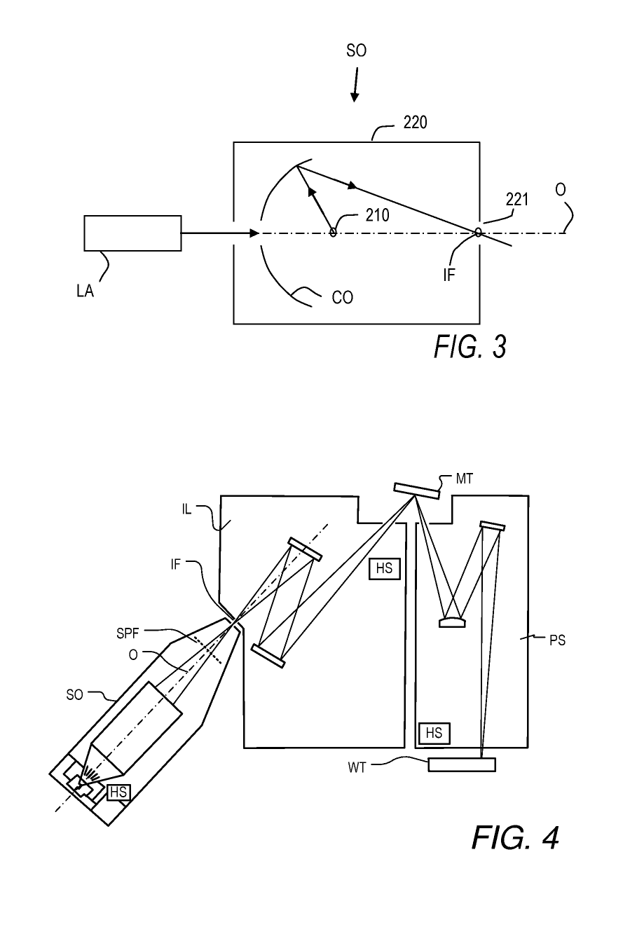

Alternatively, the source collector module SO may be part of an LPP radiation system as shown in FIG. 3. A laser LA is arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

FIG. 4 shows an alternative arrangement for an EUV lithographic apparatus in which the spectral purity filter SPF is of a transmissive type, rather than a reflective grating. The radiation from source collector module SO in this case follows a straight path from the collector to the intermediate focus IF (virtual source point). In alternative embodiments, not shown, the spectral purity filter 11 may be positioned at the virtual source point 12 or at any point between the collector 10 and the virtual source point 12. The filter can be placed at other locations in the radiation path, for example downstream of the virtual source point 12. Multiple filters can be deployed. As in the previous examples, the collector CO may be of the grazing incidence type (FIG. 2) or of the direct reflector type (FIG. 3).

Due to the requirement to perform EUV lithography in a vacuum environment, vacuum clamps cannot be used to clamp the mask/reticle to the support/chuck. Consequently electrostatic clamps are used instead. These use electrodes in the chuck to generate an electrical field, and consequently coulomb forces, between the reticle chuck and reticle (or substrate to the substrate chuck). Such electrostatic clamps are well known.

Contamination, in the form of particles, between the backside of the clamped reticle and the chuck can result in frontside distortions significant enough to result in overlay errors (lateral offsets between successive layers on the substrate), which can render the substrate unusable.

Presently there is no sensor in place to measure such contamination. The solution proposed is to measure the reticle flatness (and/or backside contamination) with an array of capacitive sensors. This array is able to measure the shape of the reticle. It is preferred that one capacitive sensor is provided per burl. Two main embodiments are proposed.

In the first embodiment, it is proposed to measure the backside deformation when the reticle is chucked with a sensor integrated in the reticle stage. There are several advantages to this:
Resolution required is less compared to measuring the frontside;
No alignment required (compared to a frontside sensor); the sensor is intrinsically aligned;
No pattern issue: the backside is measured, which is flat.

However, this solution does mean that there is increased complexity in reticle stage manufacturing. Still, with one of the solutions presented, the fabrication process is virtually unaffected. Also, other frontside deformations (non-flatness due to temperature, material-non-uniformity, etc.) would not be easily detected with such an embodiment.

In the second embodiment, it is proposed to use an external array of capacitive sensors to measure the actual frontside. The array of sensors should be compact enough to fit in an EUV inner pod, so that it could be moved under the reticle by the robot arm. A set of actuators position the sensor in close proximity of the reticle. Feedback can be given by the capacitive array itself.

Advantages of this embodiment include:
Potential for detecting sub nm bumps;
Compact since the sensor can fit in an EUV inner pod;
No modification of the reticle stage is required;
Backward compatible with earlier machines.

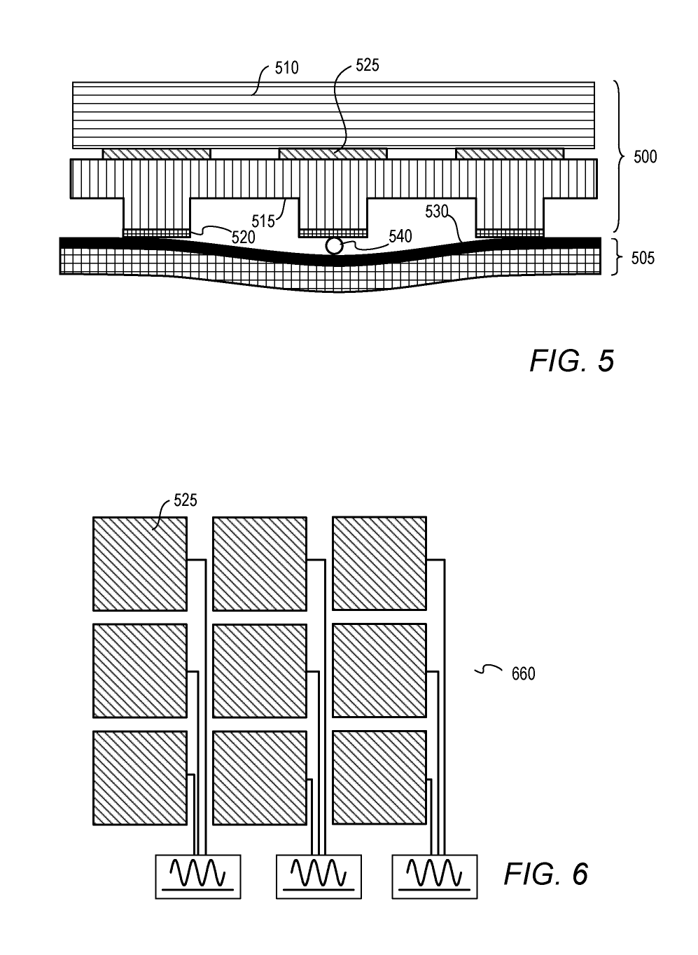

FIGS. 5 and 6 illustrate the first embodiment which integrates the capacitive sensor array with the chuck. It shows chuck 500 and reticle 505. Chuck 500 comprises first insulating layer 510 and second insulating layer 515, both of which may be glass layers, burls 520, to help reduce the impact of contamination between chuck 500 and reticle 505, and an array 660 of clamping electrodes 525. The reticle 505 comprises a conducting layer 530. The basic operation of an electrostatic clamp is well known and will not be discussed further.

Sometimes contamination in the form of one or more particles 540 become trapped between burl 520 and the reticle 505 backside. This can cause a deformation in the reticle, as illustrated. It is proposed, in this first embodiment, to measure the shape deformation of the reticle 505 due to contamination 540 at the backside by measuring the distance between the chuck 500 and the reticle 505 with a capacitive sensor array 660 that is integrated with the chuck 500. In this way, the sensor needs to be able to measure out-of-plane backside deformations at a stand-off distance of about 10-100 μm.

In this specific embodiment, the capacitor plates 525 of the capacitive sensor array 660 are integrated with the electrostatic clamp 525. When the capacitive sensor array 660 is integrated with the current electrostatic clamp 525, the clamp 525 can be subdivided into smaller plates (for example, one per burl 520) that are supplied with both DC and AC voltage signals. The DC voltage is used for clamping, whereas the AC voltage is utilized for measuring the capacitance of the plate 525 with respect to the reticle 505. Using the array 660 in this way, it is possible to identify local deformations by noting a significant difference in capacitance of one (or more) plates 525 compared to the nominal capacitance of the array plates 525, and the size of these deformations by the size of the difference.

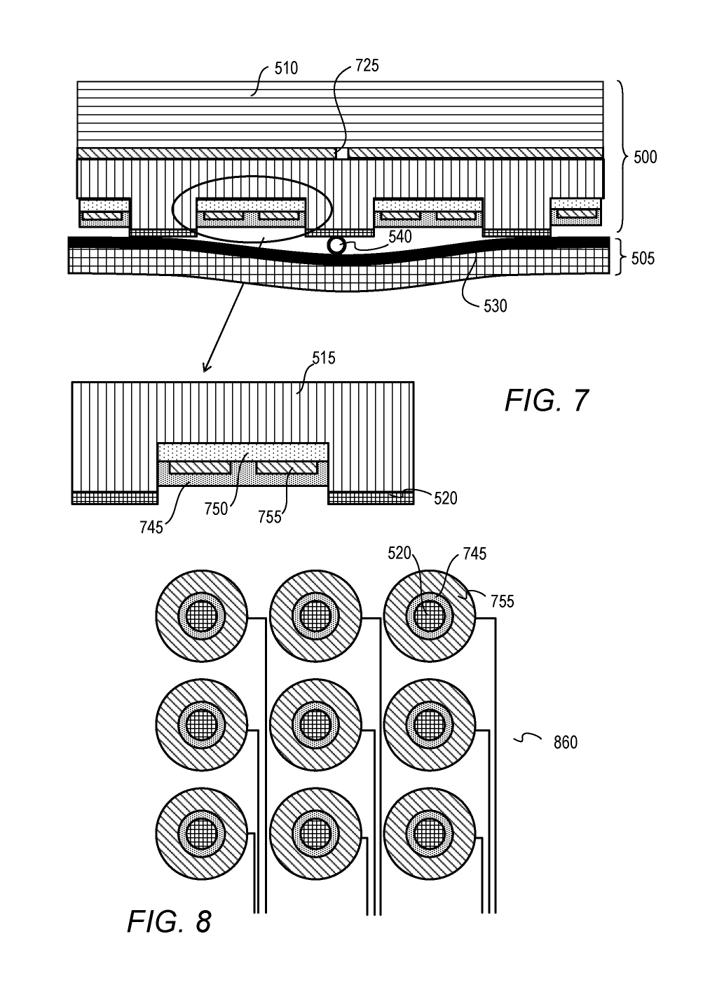

FIGS. 7 and 8 show a variation on the first main embodiment. The same labels are used for elements that are alike those of FIGS. 5 and 6. In this embodiment the sensor capacitor plates 755 of the array 860 are deposited/plated on top of the chuck 500. Recently, the required manufacturing steps of this solution have been explored successfully for the development of tin-film heaters on top of wafer tables. Shown around each burl 520 is a coating layer 750, with the sensor capacitor plates 755 around each burl, with isolation 745 isolating each sensor capacitor plate 755. More conventional (separate) clamping electrodes 725 are used on the chuck 500.

In this arrangement the sensor capacitor plates 755 are close to the reticle 505, enhancing resolution of the measurement. As said previously, conventional clamping electrodes 725 are used in combination with the capacitor plates 755 in this arrangement. However, in an alternative arrangement the capacitor plates 755 between the burls 520 could function as the clamp electrodes in a similar manner to the arrangement of FIGS. 5 and 6, the clamp electrodes 725 in this case not being required.

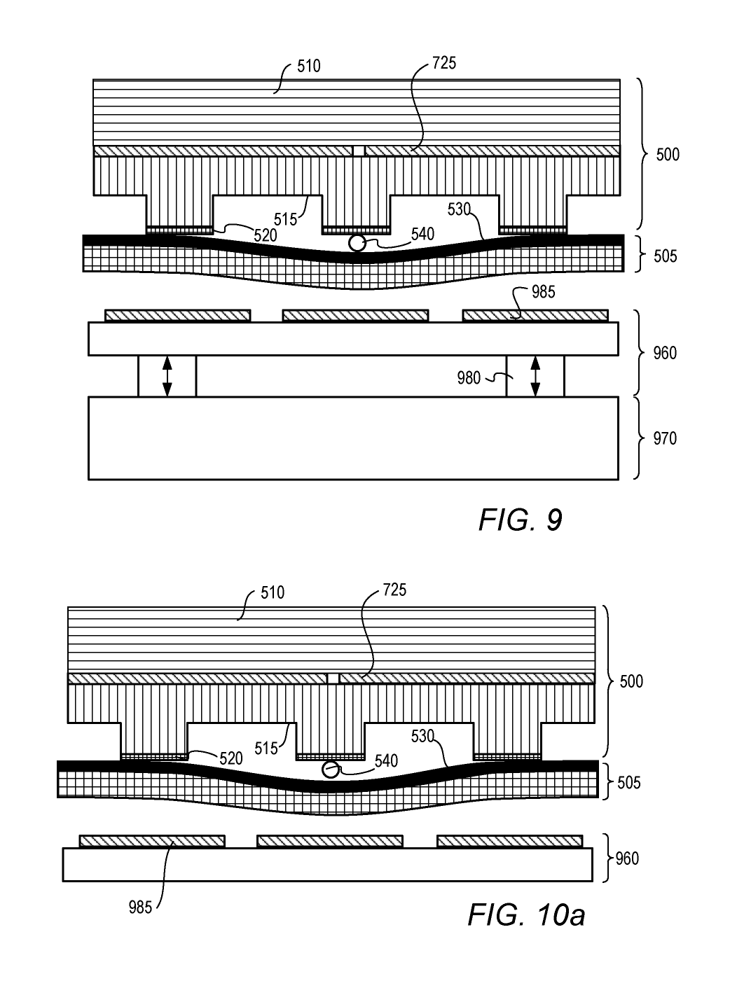

FIG. 9 shows a second main embodiment wherein a separate capacitive sensor array is used to measure reticle 505 flatness on the frontside of the reticle. Shown is a capacitive sensor array 960 comprised of individual sensor capacitor plates 985 mounted on a reticle handler 970 via integrated short stroke actuators 980 which enable relative movement between capacitive sensor array 960 and reticle 505.

This sensor array 960 is positioned underneath the reticle 505, with the actuators 980 of the reticle hander 970 positioning the sensor array 960 (in this example) at a stand-off distance of about 10 μm (see FIG. 3). The stand-off distance is controlled through the closed-loop control system of the short-stroke actuators 980 and the capacitive sensor array 960 which measures the relative position of the reticle 505 with respect to the capacitive sensor array 960. In one embodiment, the capacitive sensor array 960 itself can be used for this purpose.

The capacitive sensor array 960 is again used to measure the shape of the reticle 505. In one operational embodiment the capacitive sensor array 960 is used to make absolute measurements with the capacitive sensor array 960 being calibrated against a “holy” reference and measures the shape of the reticle 505 with respect to this reference. In this embodiment the capacitive sensor array 960 may have an absolute resolution of about 1 nm.

In another operational embodiment the capacitive sensor array 960 measures the shape of the reticle 505 with high and low clamping voltage, i.e., 500-1000V and 2500-3500V. The difference between these measurements can indicate whether the reticle 505 is lying against the burls 520 at all places or not. In case there is contamination 540 between the reticle 505 and the burl 520, the reticle 505 will bend slightly when the clamp becomes active. In this “dynamic measurement” operational embodiment the capacitive sensor array 960 sensor may have a dynamic resolution of about 0.1 nm.

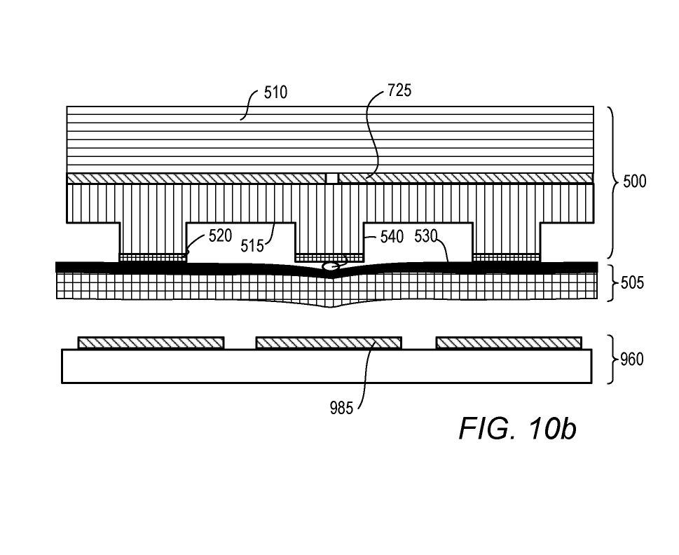

FIGS. 10a and 10b illustrate this dynamic measurement operational embodiment. FIG. 10a shows the arrangement of FIG. 9 with the clamp operated at a low clamp force. FIG. 10b shows the same arrangement with the clamp operated at a high clamp force. Here it can be seen that the reticle 505 shape is varying in the region near the particle 540 (this shape variation has been exaggerated in the drawings for emphasis). This shape variation is detected by the capacitive sensor array 960.

It is preferable that the reticle 505 is not grounded (or at least this is the present arrangement, and it is preferable not to change this). In general, accurate capacitive sensors require the measurement target to be grounded. To avoid grounding of the reticle 505, a differential capacitive measurement can be used. This differential measurement uses two capacitor plates to sense the ungrounded reticle 505. Neighbouring capacitor plates 985 can be used for this purpose.

In the above examples the capacitive sensor array is integrated in the reticle stage or is external, fitted in the EUV inner pod. Both of these solutions have the drawback that manufacturability is complicated. The first solution requires modification of the reticle clamp, which is already very difficult to make, and the latter solution requires a capacitive sensor array in a very tight volume.

Therefore, in a further embodiment, it is proposed to place the capacitive sensors on a RED (reticle exchange device). Reticle exchange devices are described in (for example) WO2009/127391, which is incorporated herein by reference. A RED is able to position the sensor array underneath the reticle such that the reticle stage can scan over the sensor.

There is sufficient available area on the RED for this sensor. For example the capacitive array could be integrated in the calibration fiduciary arm of the RED. The area available on the RED is such that a greater amount of area is available for the sensor compared to the solutions described above. Moreover, only a few (e.g. 3) line (1D) arrays need to be used instead of a full 2D array with xy dimensions comparable to a reticle. This significantly decreases the amount of electronics needed for sensor read-out.

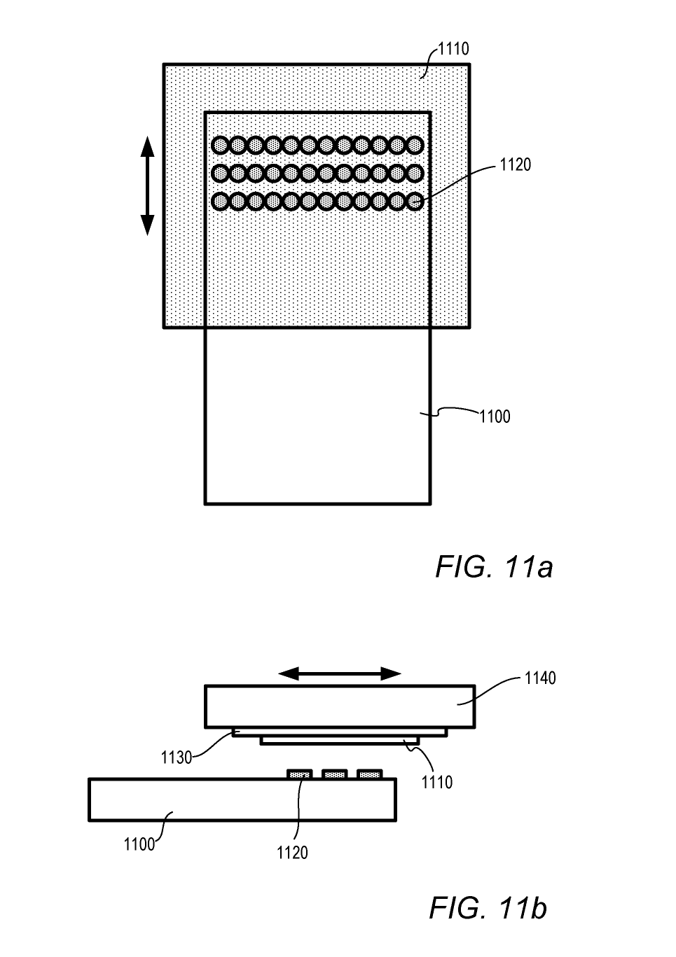

FIGS. 11a and 11b show a top view and side view respectively of this third main embodiment. It shows a RED 1100, on which is mounted a number of capacitive sensors 1120. These sensors 1120 are arranged in rows (1D arrays), there being three such rows shown here. Both the RED and the reticle stage are controlled by a controller (not shown) so as to scan the reticle 1110 surface (frontside), so as to measure its flatness. The reticle 1110 is clamped to a chuck 1140 via electrostatic clamp 1130.

In the previous sensor solutions, two measurements are required to measure reticle flatness: one measurement with a low clamp force and one measurement with a high clamp force. In this sensor topology, it is proposed to perform a single measurement without needing to change the clamp force.

A disadvantage of placing the sensor on the RED is that the RED is connected to the baseframe. Therefore, the sensor is shaking with respect to the reticle stage. This shaking is in the order of several μm and has a frequency bandwidth up to approx. 20 Hz. To correct for this shaking, a profile reconstruction algorithm is proposed. This algorithm utilizes the use of multiple line arrays at a known pitch. It is shown that this algorithm is able to distinguish between RED shaking and reticle profile.

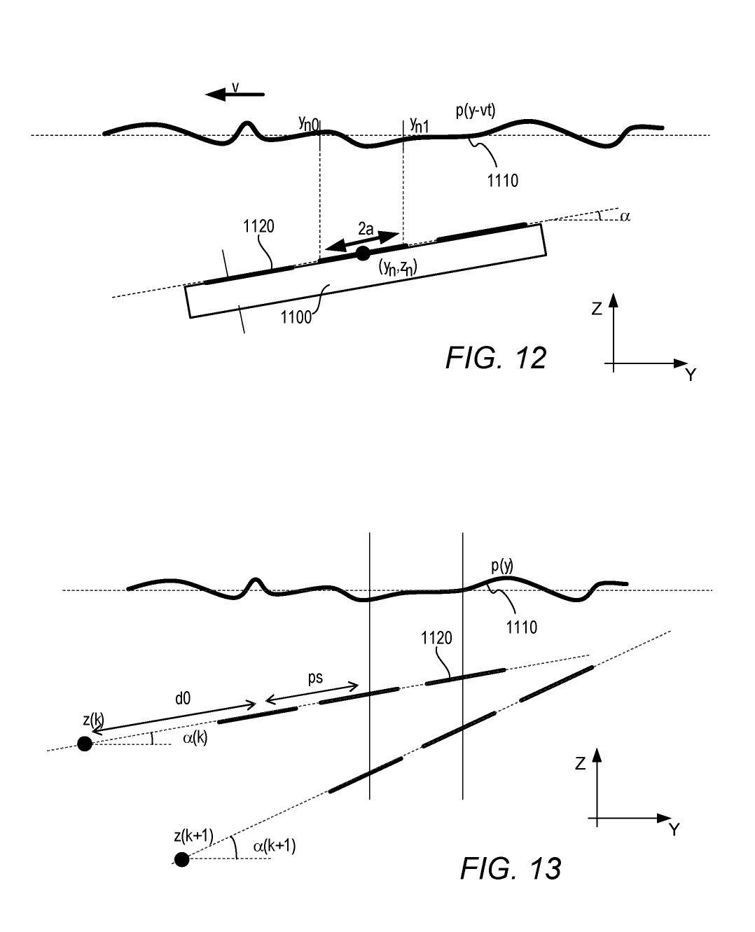

FIG. 12 illustrates the algorithm as a 1D problem. It shows the part of the RED 1100 on which the sensors 1120 are mounted. It also shows a part of the reticle 1110 profile that is to be measured. The RED will be shaking such that y, z and α will vary over time (that is: yₙ(t) zₙ(t) α(t)). Considering the reticle profile between yₙ₀ and yₙ₁ it can be shown that s_{n,k}, which is the output of sensor n at time sample k, equals:

$${s}_{n , k} = \frac{1}{2 aT} {\int }_{{t}^{′} = kT}^{( k + 1 ) T} {\int }_{{y}^{′} = {y}_{n 0}}^{{y}_{n 1}} p ( {y}^{′} - {vt}^{′} ) d {y}^{′} - {z}_{n} d {t}^{′}$$

where:

yₙ₀≈yₙ−a cos α

yₙ₁≈yₙ+a cos α

FIG. 13 illustrates a simplified scenario where it is assumed that the sample time T→0, ideal sensor electronics and a rigid planar sensor. The problem can be thought of its equivalent where the sensor is moving in y (instead of the reticle). Therefore considering points z(k) and z(k+1):

z(k)+sin(α(k))[d₀+pₛ]+s₂(k)=z(k+1)+sin(α(k+1))[d₀]+s₁(k+1)

z(k)+sin(α(k))[d₀+2pₛ]+s₃(k)=z(k+1)+sin(α(k+1))[d₀+pₛ]+s₂(k+1)

and therefore:

$$sin ( α ( k + 1 ) ) - sin ( α ( k ) ) = - \frac{1}{{p}_{s}} ( [ {s}_{2} ( k + 1 ) - {s}_{1} ( k + 1 ) ] - [ {s}_{3} ( k ) - {s}_{2} ( k ) ] )$$

$$z ( k + 1 ) - z ( k ) = sin ( α ( k ) ) [ {d}_{0} + {p}_{s} ] + {s}_{2} ( k ) - sin ( α ( k + 1 ) ) [ {d}_{0} ] - {s}_{1} ( k + 1 )$$

From which the profile can be reconstructed as follows:
to reconstruct α:

$$\begin{matrix}{α}_{r} ( k ) \approx {α}_{r} ( 0 ) + {\sum }_{q = 0}^{k - 1} sin ( α ( q + 1 ) ) - sin ( α ( q ) ) \\ = {α}_{r} ( 0 ) - \frac{1}{ps} [ ( {s}_{2} ( q + 1 ) - {s}_{1} ( q + 1 ) ) - ( ( {s}_{3} ( q ) - {s}_{2} ( q ) ) ]\end{matrix}$$

to reconstruct z:

$$\begin{matrix}{z}_{r} ( k ) = {z}_{r} ( 0 ) + {\sum }_{q = 0}^{k - 1} z ( q + 1 ) - z ( q ) \\ = {z}_{r} ( 0 ) + {\sum }_{q = 0}^{k - 1} [ {d}_{0} + {p}_{s} ] sin ( {α}_{r} ( q ) ) + {s}_{2} ( q ) - [ {d}_{0} ] sin ( {α}_{r} ( q + 1 ) ) - {s}_{1} ( q + 1 )\end{matrix}$$

and therefore to reconstruct profile (which will be independent of the scan speed with these assumptions):

p_{r,i}(k)=sᵢ(k)+zᵣ(k)+[d₀+(i−1)pₛ]sin αᵣ(k)

Therefore it can be shown that reconstruction of the profile to nanometre accuracy can be achieved with μm magnitude RED shaking. For this to be the case, the sensor pitch and sensor dimensions should be known accurately (e.g. within an order of magnitude of a micrometre.

While specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The term “lens”, where the context allows, may refer to any one or combination of various types of optical components, including refractive, reflective, magnetic, electromagnetic and electrostatic optical components.

While specific embodiments of the invention have been described above, it will be appreciated that the invention may be practiced otherwise than as described. For example, some operational steps or aspects of the invention may take the form of a computer program containing one or more sequences of machine-readable instructions describing a method as disclosed above, or a data storage medium (e.g. semiconductor memory, magnetic or optical disk) having such a computer program stored therein. The descriptions above are intended to be illustrative, not limiting. Thus it will be apparent to one skilled in the art that modifications may be made to the invention as described without departing from the scope of the claims set out below.

1. An electrostatic clamp apparatus constructed to support a patterning device of a lithographic apparatus, comprising:
a support structure against which said patterning device is supported;
clamping electrodes for providing a clamping force between the support structure and patterning device, and
an array of capacitive sensors operable to measure the shape of said patterning device.

2. The apparatus of claim 1, wherein said array is a two-dimensional array having an area similar to the surface area of said patterning device.

3. The apparatus of claim 1, wherein the array of capacitive sensors are comprised within said support structure.

4. The apparatus of claim 3, wherein said support structure is provided on a supporting surface with a plurality of protuberances against which said patterning device is clamped and a separate sensor of said array is provided in the vicinity of each protuberance and said sensors are applied to said supporting surface such that each sensor is applied substantially around a protuberance.

5. (canceled)

6. The apparatus of claim 4, wherein said array of capacitive sensors are integral with said clamping electrodes.

7. The apparatus of claim 6, wherein each of said integral clamping electrodes/capacitive sensors are provided with a DC power supply for provision of said clamping force and an AC power supply for operation as said array of capacitive sensors.

8. The apparatus of claim 1, wherein the patterning device has a first side that is operable to be clamped against said support structure, and a second side; and
wherein said array of capacitive sensors being located adjacent said second side and being operable to measure deformations on said second side.

9. (canceled)

10. The apparatus of claim 8, wherein said apparatus comprises an actuator for moving said array of capacitive sensors relative to said patterning device in the direction normal to the plane of a patterning surface of said patterning device.

11. The apparatus of claim 8, wherein said apparatus comprises a closed-loop control system operable to measure the relative position of the patterning device with respect to the array of capacitive sensors.

12. The apparatus of claim 11, wherein said apparatus is operable to use the capacitive sensor array for said measurement of the relative position of the patterning device with respect to the array of capacitive sensors.

13. The apparatus of claim 8, wherein said apparatus is operable such that the capacitive sensor array performs absolute measurements in which the capacitive sensor array measures the shape of the reticle with respect to a predetermined reference.

14. The apparatus of claim 8, wherein said apparatus is operable such that the capacitive sensor array performs relative measurements, each relative measurement being obtained from first measurements taken when said clamping electrodes are operated to exert a first clamping force and second measurements taken when said clamping electrodes are operated to exert a second clamping force, different to said first clamping force.

15. The apparatus of claim 14, wherein said second clamping force is higher than said first clamping force.

16. The apparatus of claim 15, wherein said apparatus is operable such that the capacitive sensor array performs differential measurements, each differential measurement being performed with two sensors of said capacitive sensor array.

17. The apparatus of claim 8, wherein said support structure is provided on a supporting surface with a plurality of protuberances against which said patterning device is clamped and a separate sensor is provided in the vicinity of each protuberance.

18. The apparatus of claim 1, wherein the array of capacitive sensors are comprised within a patterning device exchange apparatus which forms part of said lithographic apparatus, said a patterning device exchange apparatus being for moving and exchanging a patterning device;
wherein said patterning device exchange apparatus is operable to scan said array of capacitive sensors over the surface of the patterning device being measured.

19.-21. (canceled)

22. The apparatus of claim 18, wherein said electrostatic clamp apparatus is operable to distinguish between the reticle profile and any unintentional movement of the patterning device exchange apparatus relative to the reticle.

23. The apparatus of claim 22, wherein said distinguishing is performed algorithmically.

24. A lithographic apparatus comprising:
an illumination system configured to condition a radiation beam;
an electrostatic clamp apparatus as claimed in any preceding claim, the patterning device being capable of imparting the radiation beam with a pattern in its cross-section to form a patterned radiation beam;
a substrate table constructed to hold a substrate; and
a projection system configured to project the patterned radiation beam onto a target portion of the substrate.
